(19) United States
(12) Patent Application Publication
(10) Pub. No.: US 2011/0304003 A1
(43) Pub. Date: Dec. 15, 2011

(54) SEMICONDUCTOR DEVICE, CAMERA MODULE, AND MANUFACTURING METHOD OF SEMICONDUCTOR DEVICE

(76) Inventors: Kazumasa Tanida, Oita (JP); Naoko Yamaguchi, Kanagawa (JP); Satoshi Hongo, Oita (JP); Hideo Numata, Oita (JP)

(21) Appl. No.: 13/152,057

(22) Filed: Jun. 2, 2011

(30) Foreign Application Priority Data
Jun. 9, 2010 (JP) 2010-131803

(51) Int. Cl. H01L 31/0224; H01L 31/18

(52) U.S. Cl. 257/447; 257/459; 438/98; 257/E31.125

(57) ABSTRACT

According to the embodiments, a semiconductor substrate, an active layer that is formed on one surface of the semiconductor substrate, a wiring layer that is formed on the active layer and includes a wire to be a convex portion on a surface that is not in contact with the active layer, a insulation layer that is formed on the wiring layer to have a concave portion, an embedded layer that is provided on the concave portion of the insulation layer, a bonding layer that is provided on the insulation layer and the embedded layer, and a substrate that is bonded to the bonding layer to face one surface of the semiconductor substrate are included.

### CROSS-REFERENCE TO RELATED APPLICATIONS

This application is based upon and claims the benefit of priority from the prior Japanese Patent Application No. 2010-131803, filed on Jun. 9, 2010; the entire contents of which are incorporated herein by reference.

### FIELD

Embodiments described herein relate generally to a semiconductor device, a camera module, and a manufacturing method of a semiconductor device.

### BACKGROUND

There is proposed a back-illuminated image sensor in which a light receiving surface of a photodiode is provided on a back surface of a semiconductor substrate as an alternative to a front-illuminated image sensor. In the back-illuminated image sensor, wires and excessive films need not be formed on the light receiving surface, so that sensitivity higher than the front-illuminated image sensor can be obtained. In this case, in order to efficiently collect light incident on the back surface into the photodiode, the semiconductor substrate needs to be thinned. The thickness of the semiconductor substrate, for example, needs to be thinner than 20 μm in the case of receiving visible light for preventing the resolution from being impaired by the time charges generated in the light receiving surface are diffused and collected in the photodiode.

Such a back-illuminated image sensor is formed, for example, by the following method. First, a semiconductor substrate on the surface of which a photodiode and an integrated circuit are formed is prepared. Then, a support substrate having approximately the same diameter as the semiconductor substrate is bonded to the front surface side of the semiconductor substrate. This support substrate functions as a reinforcement when thinning the semiconductor substrate to near the photodiode from the back surface side thereof to form a light receiving surface. Next, an antireflection film, a color filter, a condenser microlens, and the like are provided on the light receiving surface.

Furthermore, after forming an electrode portion, which is electrically connected to the integrated circuit formed on the semiconductor substrate, on the back surface of the semiconductor substrate, a bonded body of the semiconductor substrate and the support substrate is cut and divided by a dicing blade. The divided chip is adhered to a ceramic package or the like, and the electrode portion of the chip and wires formed in the ceramic package are electrically connected by wire bonding. In this manner, a semiconductor device having a function of a so-called back-illuminated image sensor is formed that receives an energy line such as light and electrons radiated from the back surface side and collects it in the photodiode.

For the above semiconductor device, thinning is performed from the back surface of the semiconductor substrate toward a layer on the front surface side in which the photodiode is formed. At this time, the semiconductor device is thinned partway by a mechanical grinding or a chemical mechanical polishing (CMP). The semiconductor substrate is desirably thinned as much as possible for collecting an energy line into the photodiode efficiently.

However, thinning of the semiconductor substrate results in concentration of a residual stress, which is generated when the integrated circuit (formed of a metal wire and a insulation film) is formed on the surface of the semiconductor substrate, on the bonded surface side of the semiconductor substrate and the support substrate. Therefore, bonding the semiconductor substrate to the support substrate is desirably performed by a bonding method that reduces the influence of the residual stress. A high-temperature process is needed for forming the electrode on the back surface of the semiconductor substrate, so that the bonding method of the semiconductor substrate and the support substrate is desirably a method without via an organic material. Thus, as the bonding method of the semiconductor substrate and the support substrate, it is desirable to use a direct bonding method in which the surface portion (insulation film) of the semiconductor substrate and the surface portion (insulation film, or silicon, for example) of the support substrate are directly connected inorganically.

Moreover, when preparing the semiconductor substrate on the surface of which the photodiode and the integrated circuit are formed, an electrical test by a prober is desirably performed for checking an electrical performance of a chip in a wafer. Therefore, wires of the uppermost layer of the integrated circuit formed on the surface are desirably formed of aluminum (Al) or an alloy thereof (Al—Si, Al—Si—Cu).

However, because an Al wiring pattern is formed in a convex shape, even if a insulation film before bonding the support wafer is thickly applied and is planarized by the CMP, irregularities due to the Al wire do not disappear and remain as a gap (unbonded portion) at a bond interface. Particularly, in the direct bonding method, presence of irregularities results in increasing the possibility of forming an unbonded portion. If the unbonded portion is formed, when thinning the semiconductor substrate, separation of the semiconductor substrate and the support substrate, fracture of the semiconductor substrate, and the like may occur, which decreases the yield in generation of the semiconductor device. Moreover, even if the separation or the fracture does not occur, presence of the unbonded portion may result in deformation of the thin semiconductor substrate, so that the light receiving surface may be distorted and therefore the imaging property may degrade.

### BRIEF DESCRIPTION OF THE DRAWINGS

FIG. 1 is a schematic diagram illustrating an example of a cross section of a semiconductor device according to a first embodiment;

FIG. 2A to FIG. 2I are diagrams illustrating an example of a manufacturing process of the semiconductor device in the first embodiment;

FIG. 3 is a schematic diagram illustrating an example of a cross section of a semiconductor device according to a second embodiment;

FIG. 4A to FIG. 4I are diagrams illustrating an example of a manufacturing process of the semiconductor device in the second embodiment;

FIG. 5 is a schematic diagram illustrating an example of a cross section of a camera module according to a third embodiment;

FIG. 6 is a schematic diagram illustrating an example of a cross section of a camera module according to a fourth embodiment;

FIG. 7 is a schematic diagram illustrating an example of a cross section of a wafer according to a fifth embodiment; and

FIG. 8A to FIG. 8G are diagrams illustrating an example of a manufacturing process of the wafer in the fifth embodiment.

### DETAILED DESCRIPTION

A semiconductor device according to embodiments includes a semiconductor substrate, an active layer that is formed on one surface of the semiconductor substrate, and a wiring layer that is formed on the active layer and includes a wire to be a convex portion on a surface that is not in contact with the active layer. Moreover, in the semiconductor device according to embodiments, a thickly layer is formed on the wiring layer to have a concave portion. Furthermore, in the semiconductor device according to embodiments, an embedded layer is provided on the concave portion of the insulation layer and a bonding layer is provided on the insulation layer and the embedded layer. Moreover, the semiconductor device according to embodiments includes a substrate that is bonded to the bonding layer to face the one surface of the semiconductor substrate.

A semiconductor device, a camera module, and a manufacturing method of a semiconductor device according to the embodiments will be explained below in detail with reference to the accompanying drawings. The present invention is not limited to these embodiments.

### First Embodiment

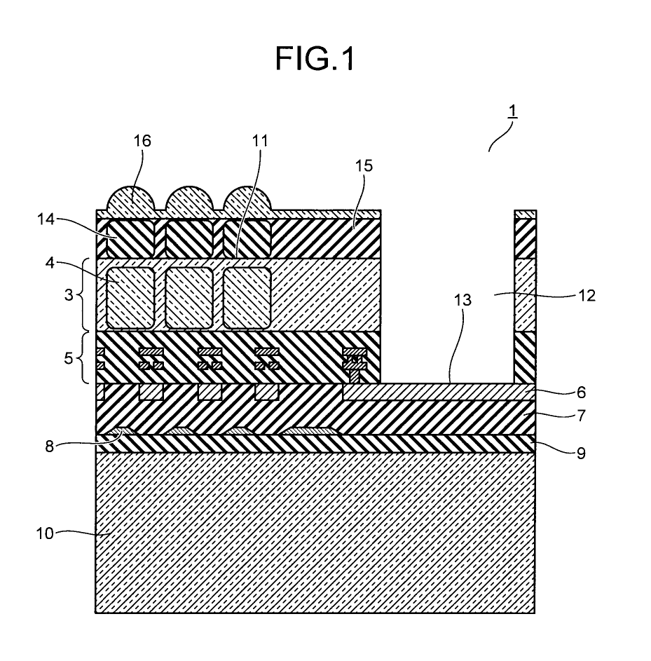

FIG. 1 is a schematic diagram illustrating an example of a cross section of a semiconductor device 1 according to the first embodiment. The semiconductor device 1 in the present embodiment is configured as a so-called back-illuminated image sensor that detects light received from the back surface by a photodiode formed on the front surface side.

As shown in FIG. 1, the semiconductor device 1 in the present embodiment includes an active layer 3 in which photodiodes 4 and transistors (not shown) are formed. The active layer 3 is a semiconductor substrate in which the photodiodes 4 and the transistors (not shown) are formed. A multilayer wiring layer (wiring layer) 5 is formed on a first surface side (front side of the semiconductor substrate) of the active layer 3, and wires 6 are formed on the uppermost layer (lowermost portion of the multilayer wiring layer 5 in FIG. 1) of the multilayer wiring layer 5. The wires 6 are covered by a insulation layer 7. A bonding layer 9 is formed on the insulation layer 7 (under the insulation layer 7 in FIG. 1), and the insulation layer 7 and a support substrate 10 are bonded via the bonding layer 9. Moreover, an embedded layer 8 is formed in part of a region between the insulation layer 7 and the bonding layer 9.

On a second surface side (back side of the semiconductor substrate) of the active layer 3, a light receiving surface 11 that receives an energy line such as light and electrons and collects it in the photodiode 4 is formed, and moreover, a color filter layer 15 including color filters 14 is formed. On the upper portion (the second surface side) of the color filter layer 15, a microlens 16 is formed. Moreover, an aperture 12 that penetrates through the active layer 3 and the multilayer wiring layer 5 is provided in the upper portion on the right side in FIG. 1, and an electrode 13 is formed in the lower portion of the aperture 12.

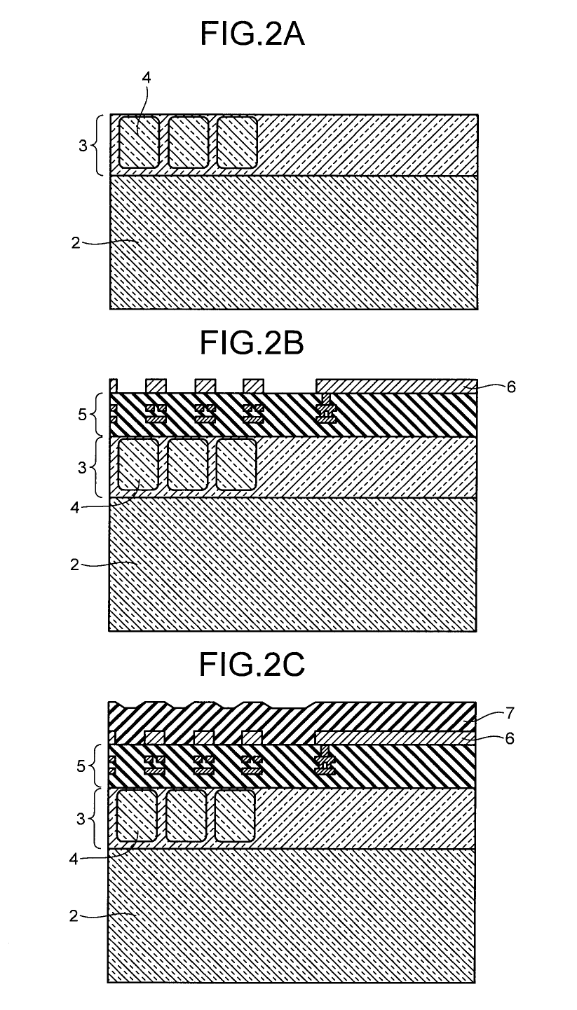

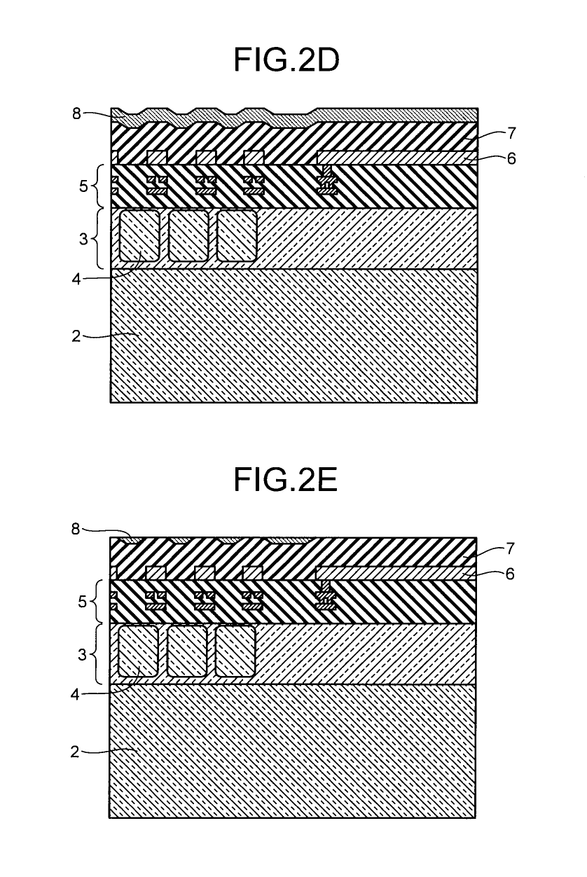

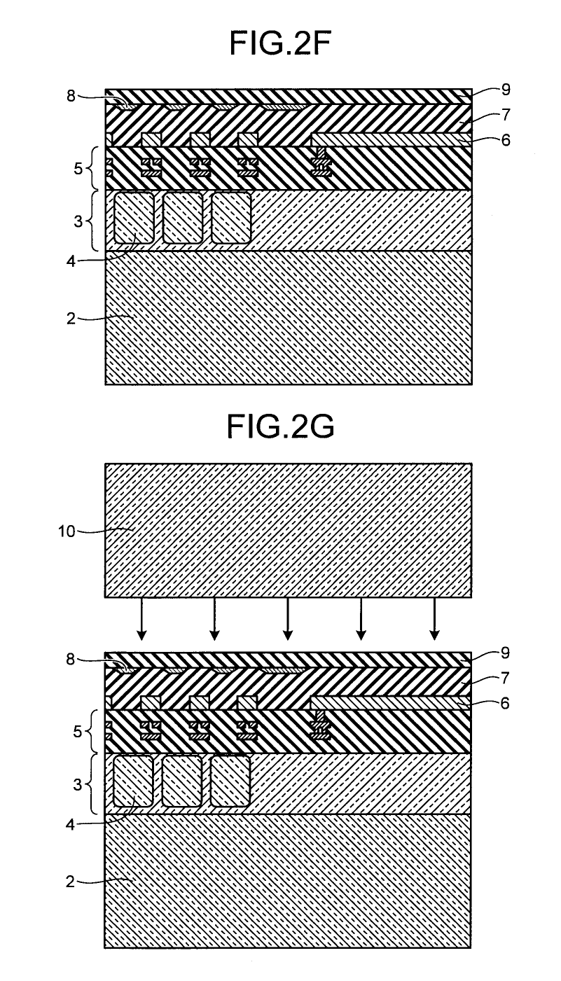

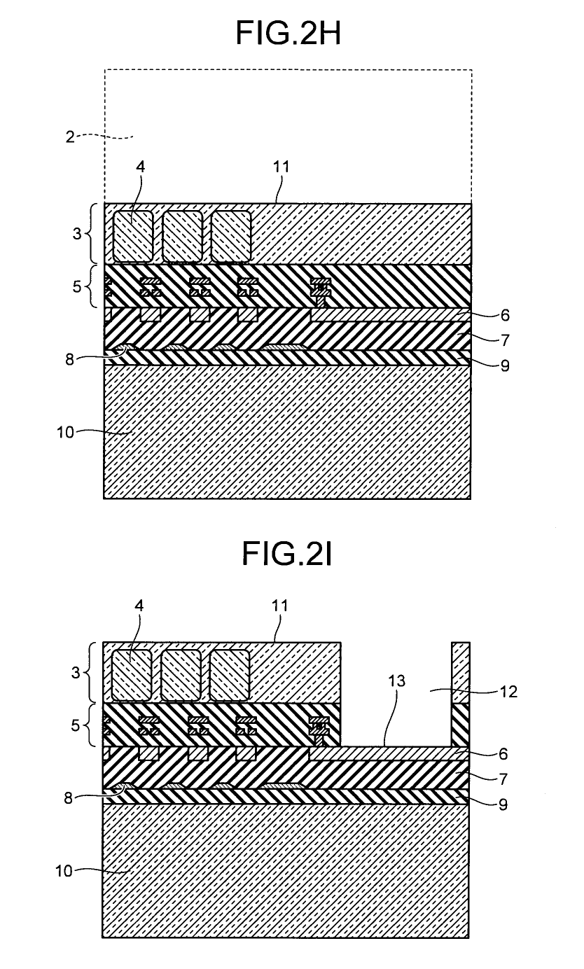

FIG. 2A to FIG. 2I are diagrams illustrating an example of the manufacturing process of the semiconductor device 1 in the first embodiment. FIG. 2A to FIG. 2I illustrate schematic cross sections of the semiconductor device 1 in respective processes. The parts denoted by the same reference numerals in the drawings indicate the same or corresponding part. In the following, the manufacturing process of the semiconductor device 1 in the present embodiment is explained with reference to FIG. 2A to FIG. 2I.

First, in the first process shown in FIG. 2A, a semiconductor substrate 2, on the first surface side of which the active layer 3 in which the photodiodes 4 and transistors (not shown) are formed, is prepared. As the semiconductor substrate 2, a substrate made of any material can be used, however, for example, a silicon substrate or the like can be used.

In the second process shown in FIG. 2B, the multilayer wiring layer 5 formed of a metal material, a insulation material, or the like is formed on the active layer 3 by a sputtering method, the CVD (Chemical Vapor Deposition) method, a vapor deposition method, a plating method, or the like using a mask (not shown) having a predetermined pattern.

As the metal material forming the multilayer wiring layer 5, for example, at least any one of a high-resistance metal material (Ti, TiN, TiW, Ni, Cr, TaN, CoWP, or the like) and a low-resistance metal material (Al, Al—Cu, Al—Si—Cu, Cu, Au, Ag, or the like) can be used as a single layer or a plurality of stacked layers. Moreover, the insulation material forming the multilayer wiring layer 5 is, for example, formed by the CVD method, a spin coating method, or a spray coating method. As the insulation material forming the multilayer wiring layer 5, for example, at least any one of a silicon oxide film (SiO₂), a silicon nitride film (SiNx), a SiOF (Fluorine-doped SiO₂) film, a porous SiOC (Carbon-doped SiO₂) film, a polyimide film, a BCB (benzocyclobutene) film, and an epoxy resin film can be used as a single layer or a plurality of stacked layers. FIG. 2B illustrates the case where the multilayer wiring layer 5 has two layers as an example, however, the number of the layers can be three or more.

Moreover, the wires 6, which are electrically connected to the multilayer wiring layer 5, are formed on the multilayer wiring layer 5. The wires 6 are, for example, formed of at least any one of a high-resistance metal material (Ti, TiN, TiW, Ni, Cr, TaN, CoWP, or the like) and a low-resistance metal material (Al, Al—Cu, Al—Si—Cu, Cu, Au, Ag, or the like) as a single layer or a plurality of stacked layers. The wires 6 are formed into a convex shape in part of a region on the multilayer wiring layer 5.

In the third process shown in FIG. 2C, the insulation layer 7 is formed on the multilayer wiring layer 5 and the wires 6 by the CVD method, the spin coating method, or the spray coating method. The insulation layer 7 is, for example, formed of at least any one of a silicon oxide film (SiO₂), a silicon nitride film (SiNx), a silicon oxynitride film (SiON), a SiOF (Fluorine-doped SiO₂) film, a porous SiOC (Carbon-doped SiO₂) film, a polyimide film, a BCB (benzocyclobutene) film, and an epoxy resin film as a single layer or a plurality of stacked layers. At this time, the surface of the dielectric layer 7 becomes a convex portion on the wires 6 and a concave portion on the portion other than the wires 6.

Next, in the fourth process shown in FIG. 2D, the embedded layer 8 is formed on the insulation layer 7. At this time, the embedded layer 8 is formed on the concave portions and the convex portions on the insulation layer 7. The embedded layer 8 is, for example, formed of at least any one of a high-resistance metal material (Ti, TiN, TiW, Ni, Cr, TaN, CoWP, or the like) and a low-resistance metal material (Al, Al—Cu, Al—Si—Cu, Cu, Au, Ag, or the like) as a single layer or a plurality of stacked layers.

Next, in the fifth process shown in FIG. 2E, the embedded layer 8 formed on the insulation layer 7 is thinned by a chemical mechanical polishing from the exposed side on which the embedded layer 8 is not in contact with the insulation layer 7. At this time, if the embedded layer 8 is made of a metal material, the selectivity in the CMP rate with respect to the insulation layer 7 becomes high, so that the embedded layer 8 can be removed while leaving only in the concave portions of the insulation layer 7 (the embedded layer 8 on the convex portions of the insulation layer 7 is removed).

When the surface of the insulation layer 7 has a shape having a convex portion and a concave portion (the surface is not flat), if the insulation layer 7 is bonded to a different substrate such as the support substrate 10, an unbonded portion may be formed. If an unbonded portion is present, when thinning the semiconductor substrate, separation of the semiconductor substrate and the different substrate, fracture of the thin semiconductor substrate, or the like may occur. Therefore, in the present embodiment, the surface of the insulation layer 7 is planarized by using the embedded layer 8.

Next, in the sixth process shown in FIG. 2F, the bonding layer 9 is formed on the insulation layer 7 and the embedded layer 8 by the CVD method, the spin coating method, the spray coating method, or the like. The bonding layer 9 is, for example, formed of at least any one of a silicon oxide film (SiO₂), a silicon nitride film (SiNx), a SiOF (Fluorine-doped SiO₂) film, a porous SiOC (Carbon-doped SiO₂) film, a polyimide film, a BCB (benzocyclobutene) film, and an epoxy resin film as a single layer or a plurality of stacked layers. Moreover, the surface of the bonding layer 9 is planarized by the chemical mechanical polishing or the like if needed.

In the seventh process shown in FIG. 2F, the support substrate 10 having approximately the same size as the semiconductor substrate 2 is bonded to the bonding layer 9. At this time, the bonding layer 9 and the surface of the support substrate 10 can be directly bonded to each other. Alternatively, they can be bonded via metal films (not shown) of gold (Au), copper (Cu), tin (Sn), alloy thereof, or the like. The support substrate 10 can be formed of any material, and is, for example, formed of silicon (Si), gallium arsenic (GaAs), borosilicate glass, quartz glass, soda-lime glass, epoxy resin, or polyimide resin.

When the bonding layer 9 and the surface of the support substrate 10 are directly bonded to each other, organic substances such as carbon and metal contaminants such as Cu and Al on the surfaces are removed by a cleaning process (not shown) of the surface of the bonding layer 9 and the surface of the support substrate 10. The cleaning process can be, for example, a wet process such as an organic cleaning using acetone, alcohol, ozone water (O₃), or the like, and an acid and alkaline cleaning using hydrofluoric acid (HF), diluted hydrofluoric acid (DHF), sulfuric acid hydrogen peroxide mixture, ammonia hydrogen peroxide mixture, hydrochloric acid hydrogen peroxide mixture, or the like. Alternatively, the cleaning process can be a dry process such as a plasma process energized by a single gas or a plurality of gases selected from among hydrogen, nitrogen, oxygen, nitrous oxide (N₂O), argon, helium, and the like. The cleaning process can be a combination of the wet process and the dry process. Although both of the surfaces of the bonding layer 9 and the support substrate 10 are preferably processed by the cleaning process, only any one of the surfaces can be processed.

In the eighth process shown in FIG. 2H, the semiconductor substrate 2 is thinned from the second surface (back surface) by a mechanical grinding, the chemical mechanical polishing, a wet etching method, or a dry etching method, and thereafter, the light receiving surface 11 is formed on the upper portion of the photodiodes 4 of the active layer 3. At this time, the semiconductor substrate 2 is thinned up to the thickness with which an energy line such as light and electrons radiated to the light receiving surface 11 can be collected in the photodiodes 4 formed in the active layer 3 on the first surface side. For example, in the case of collecting visible light, the semiconductor substrate 2 is desirably thinned to the thickness of 20 μm or less.

In the ninth process shown in FIG. 2I, the aperture 12 is formed from the second surface side of the semiconductor substrate 2 to penetrate through the active layer 3 and the multilayer wiring layer 5. The aperture 12 is formed, for example, by a plasma etching method using a mask (not shown) having a predetermined pattern. Therefore, part of the wires 6 are exposed at the lower portion of the aperture 12 and the exposed portion is formed as the electrode 13. In the plasma etching of removing the active layer 3, for example, when the active layer 3 is formed of silicon (Si), a mixed gas of SF₆, O₂, and Ar can be used. Moreover, in the plasma etching of removing the multilayer wiring layer 5, for example, when the multilayer wiring layer 5 is a SiO₂ film or a SiNx film, a mixed gas of C₅F₈, O₂, and Ar can be used.

Moreover, on the sidewall of the aperture 12, a dielectric film (not shown) can be formed by the CVD method, the spin coating method, the spray coating method, or the like. For the dielectric film on the sidewall of the aperture 12, for example, a silicon oxide film (SiO₂), a silicon nitride film (SiNx), a SiOF (Fluorine-doped SiO₂) film, a porous SiOC (Carbon-doped SiO₂) film, a polyimide film, a BCB (benzocyclobutene) film, or an epoxy resin film can be used.

After the above first to ninth processes, the color filter layer 15 and the microlens 16 are formed on the second surface (surface of the active layer 3 opposite to the surface that is in contact with the multilayer wiring layer 5) side of the semiconductor substrate 2, whereby the semiconductor device shown in FIG. 1 is obtained. In this embodiment, the aperture 12 is formed before the color filter 14 and the microlens 16 are formed, however, it is not limited thereto and the aperture 12 can be formed after the color filter 14 and the microlens 16 are formed.

In this manner, in the present embodiment, the multilayer wiring layer 5 and the wires 6 are formed on the active layer 3 on the first surface side of the semiconductor substrate 2 and the insulation layer 7 is formed on the multilayer wiring layer 5 and the wires 6, and thereafter the embedded layer 8 is formed on the insulation layer 7. Then, after removing the embedded layer 8 except that embedded in the concave portion of the insulation layer 7, the bonding layer 9 is provided on the insulation layer 7 and the embedded layer 8, the support substrate 10 is bonded to the bonding layer 9 to face the first surface of the semiconductor substrate 2, and the semiconductor substrate 2 is thinned from the second surface side of the semiconductor substrate 2. Therefore, a gap is not generated at the bond interface with the support substrate 10, so that fracture of the active layer 3, the multilayer wiring layer 5, and the wires 6 can be prevented, thereby improving the yield. Moreover, because a gap is not generated at the bond interface with the support substrate 10, warpage and distortion of the light receiving surface 11 are reduced, thereby improving the imaging property.

Furthermore, in addition to the above basic effects, because the embedded layer 8 is formed of a metal material, when removing the embedded layer 8 except that embedded in the concave portions by performing the chemical mechanical polishing, the selectivity of the embedded layer 8 with respect to the insulation layer 7 becomes high, so that polishing can be stopped by the insulation layer 7. Therefore, the surface planarization before the bonding can be facilitated compared with the case of planarizing the insulation layer 7. If the embedded layer 8 is not provided, the insulation layer 7 needs to be planarized as much as possible and therefore the material of the insulation layer 7 needs to be a material that is easily planarized. However, in the present embodiment, planarization is performed in a state where the embedded layer 8 is provided, so that the insulation layer 7 itself does not need to be formed of a material that is easily planarized. Thus, material options for the insulation layer 7 increase and the manufacturing process is facilitated.

In the present embodiment, the back-illuminated image sensor is explained as an example of the semiconductor device 1, however, planarization using the embedded layer 8 described in the present embodiment can be applied to a semiconductor device, in which planarization of the surface is required, other than the back-illuminated image sensor. For example, in the case of stacking device wafers, if the surfaces of the wafers to be stacked are planarized by using the embedded layer 8 described in the present embodiment, a gap is not generated at bond interfaces between the wafers, so that separation, fracture, and the like of the wafers can be prevented.

Moreover, in the present embodiment, although the surface of the insulation layer 7 is planarized by embedding the embedded layer 8 in the concave portions generated in the insulation layer 7 due to the wires 6, the surface of the insulation layer 7 can be planarized by embedding the embedded layer 8 in the concave portions of the surface generated in the insulation layer 7 for a reason other than the wires 6.

### Second Embodiment

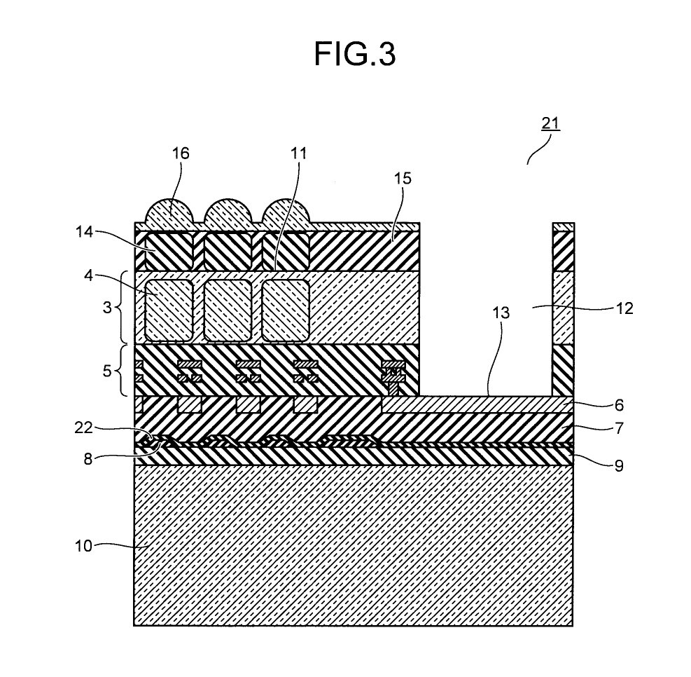

FIG. 3 is a schematic diagram illustrating an example of a cross section of a semiconductor device 21 according to the second embodiment. The semiconductor device 21 in the present embodiment is configured as a so-called back-illuminated image sensor that detects light received from the back surface by a photodiode formed on the front surface side.

The configuration of the semiconductor device 21 in the present embodiment is similar to the configuration of the semiconductor device 1 in the first embodiment except that a stopper layer 22 is added to the semiconductor device 21 in the first embodiment. As shown in FIG. 3, in the semiconductor device 21 in the present embodiment, the stopper layer 22 is formed between the embedded layer 8 and the insulation layer 7 and between the convex portions of the insulation layer 7 and the bonding layer 9. Components having similar functions to those in the first embodiment are denoted by the reference numerals same as those in the first embodiment and explanation thereof is omitted. In the following, portions different from the first embodiment are explained.

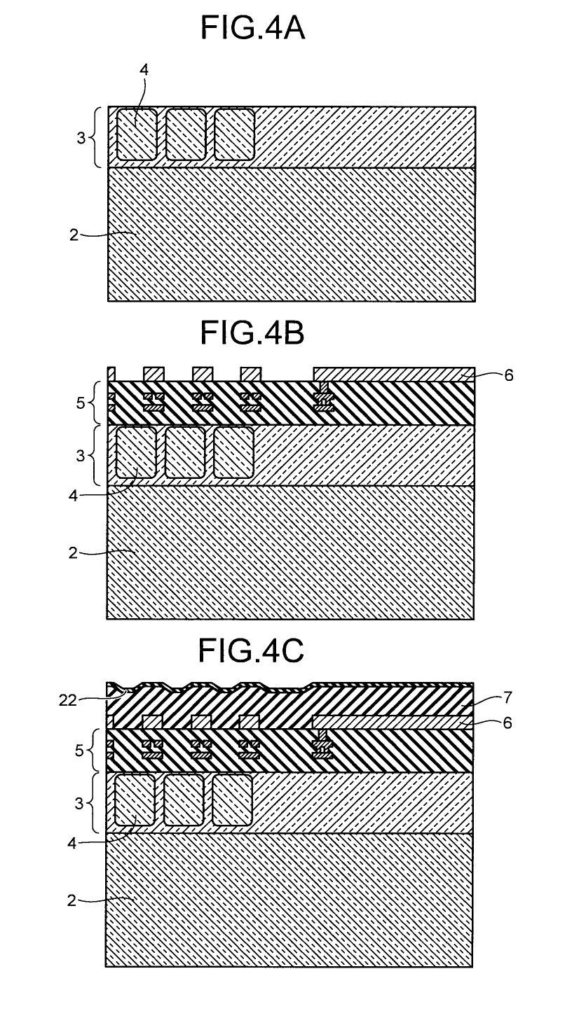

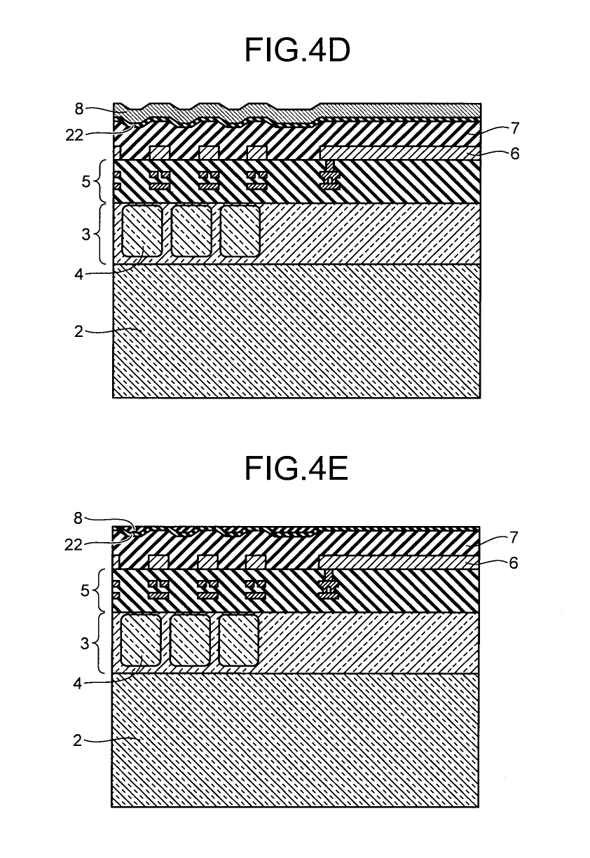

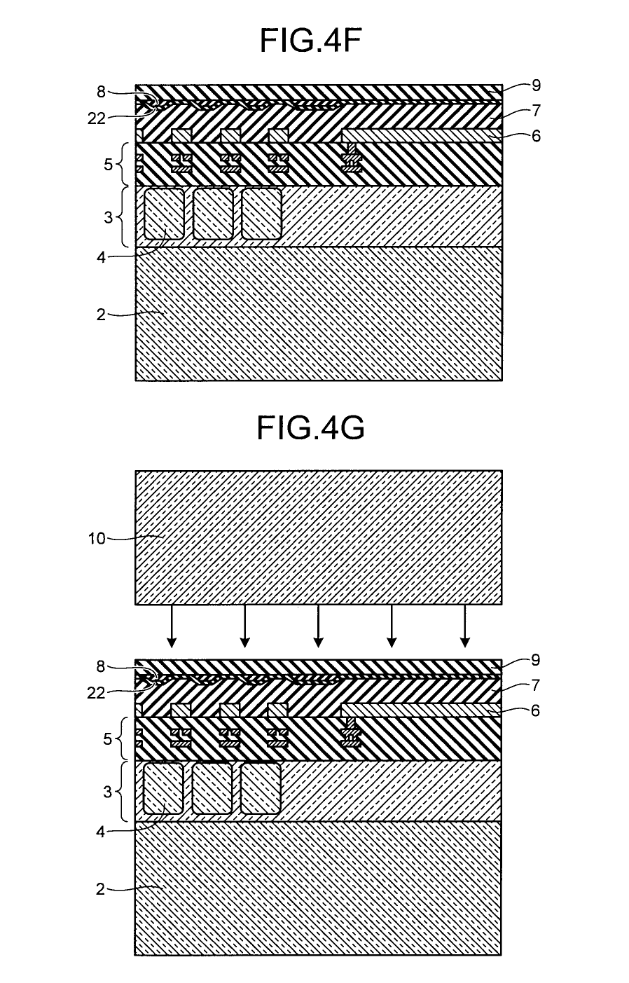

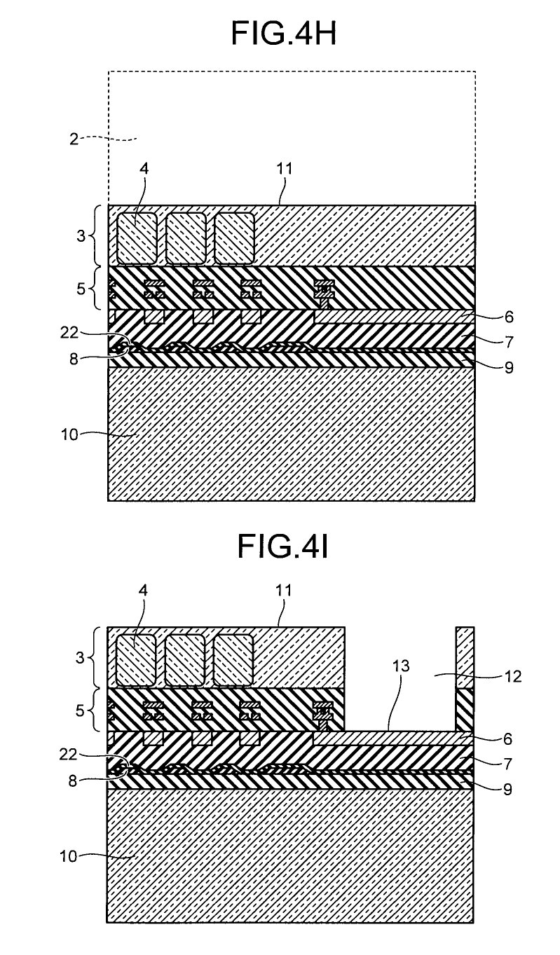

FIG. 4A to FIG. 4I are diagrams illustrating an example of the manufacturing process of the semiconductor device 21 in the second embodiment. FIG. 4A to FIG. 4I illustrate schematic cross sections of the semiconductor device 21 in respective processes. The parts given the same reference numerals in the drawings indicate the same or corresponding part. In the following, the manufacturing process of the semiconductor device 21 in the present embodiment is explained with reference to FIG. 4A to FIG. 4I.

The first process shown in FIG. 4A and the second process shown in FIG. 4B are similar to the first process and the second process in the first embodiment, respectively.

After the second process, as the third process as shown in FIG. 4C, first, the insulation layer 7 is formed on the multilayer wiring layer 5 and the wires 6 by the CVD method, the spin coating method, or the spray coating method in the similar manner to the first embodiment. Thereafter, the stopper layer 22 is formed on the insulation layer 7. As the insulation layer 7, the material similar to that in the first embodiment can be used, however, the material different from the stopper layer is used for the insulation layer 7. For example, when the stopper layer 22 is formed of a silicon nitride film (SiNx), the insulation layer 7 is formed of a material other than a silicon nitride film (SiNx).

Next, in the fourth process, as shown in FIG. 4D, the embedded layer 8 is formed on the stopper layer 22 by the CVD method, the spin coating method, the spray coating method, or the like. In the present embodiment, as the embedded layer 8, for example, a silicon oxide film (SiO₂), a silicon oxynitride film (SiON), a SiOF (Fluorine-doped SiO₂) film, a porous SiOC (Carbon-doped SiO₂) film, or the like can be used.

In the fifth process shown in FIG. 4E, the embedded layer 8 formed on the stopper layer 22 is thinned by the chemical mechanical polishing from the exposed side that is not in contact with the stopper layer 22. At this time, the embedded layer 8 (for example, SiO₂ film or SiON film) has a sufficiently high CMP rate (selectivity is high) with respect to a silicon nitride film that is the stopper layer 22, so that the embedded layer 8 can be removed while leaving only in the concave portions of the stopper layer 22. Therefore, for the stopper layer 22, a material having a sufficiently low CMP rate with respect to the embedded layer 8 is desirably used.

Next, in the sixth process shown in FIG. 4F, the bonding layer 9 is formed on the stopper layer 22 and the embedded layer 8 by the CVD method, the spin coating method, or the spray coating method. The material of the bonding layer 9 is similar to that in the first embodiment. Moreover, the surface of the bonding layer 9 is planarized by the chemical mechanical polishing or the like if needed.

The seventh process to the ninth process thereafter shown in FIG. 4G, FIG. 4H, and FIG. 4I are similar to the seventh process to the ninth process in the first embodiment. Then, the color filter 14 and the microlens 16 are formed in the similar manner to the first embodiment, whereby the semiconductor device 21 shown in FIG. 3 is obtained.

In this manner, in the present embodiment, the stopper layer 22 formed of silicon nitride is provided on the insulation layer 7 and the embedded layer 8 is formed of a dielectric film whose main component is silicon oxide. Therefore, in the chemical mechanical polishing of removing the embedded layer 8 except that embedded in the concave portions of the insulation layer 7, the selectivity of the embedded layer 8 with respect to the stopper layer 22 becomes high and therefore polishing can be stopped by a silicon nitride film that is the stopper layer 22, so that planarization is facilitated. Therefore, a gap is not generated at the bond interface with the support substrate 10, so that fracture of the active layer 3, the multilayer wiring layer 5, and the wires 6 is prevented. Thus, the mechanical reliability and the imaging property are further improved. Moreover, because a dielectric material can be used for the embedded layer 8, the insulation property of the wires 6 is further improved compared with the first embodiment, so that the electrical reliability is improved.

### Third Embodiment

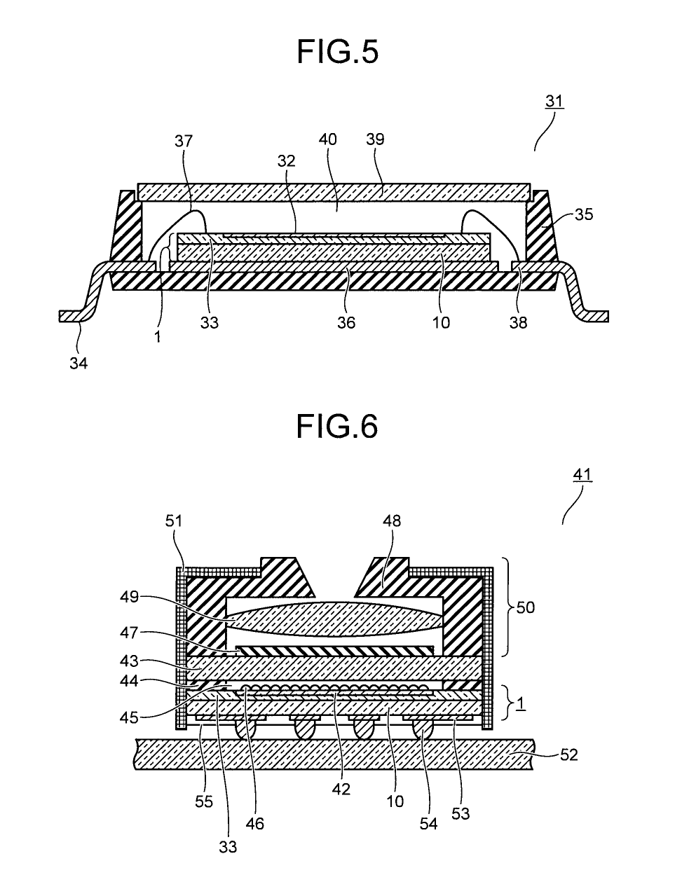

FIG. 5 is a schematic diagram illustrating an example of a cross section of a camera module 31 according to the third embodiment. The camera module 31 in the present embodiment has a QFP (Quad Flat Package) type package form and includes the semiconductor device 1 in the first embodiment as a main part thereof. In FIG. 5, the semiconductor device 1 is illustrated in a simplified manner and includes a light receiving portion 32 that includes a light receiving element, such as a photodiode, a color filter, and a microlens, a device layer 33 that includes a peripheral circuit (not shown) and a wiring layer (not shown), and the support substrate 10.

The semiconductor device 1 is adhered to an island portion 36 of a ceramic package 35 including a rectangular ring-shaped external terminal pin 34. A metal wire 37 electrically connects an electrode portion (not shown) of the semiconductor device 1 to a wire 38 formed in the ceramic package 35. A light-transmissive protective member 39 for protecting the light receiving portion 32 from being damaged or dust is arranged over the semiconductor device 1. The light-transmissive protective member 39 is adhered to the surface of the ceramic package 35 via an adhesive (not shown). In order to prevent a light condensing effect of the microlens on the light receiving portion 32 from being impaired, a clearance (cavity) 40 is provided between the light-transmissive protective member 39 and the light receiving portion 32. The camera module 31 is, for example, set in a socket (not shown) arranged on a substrate (not shown) of the imaging device and the semiconductor device 1 is electrically connected to the substrate (not shown) via the metal wire 37, the wire 38, and the external terminal pin 34.

In such camera module 31, light reached from an imaging object is condensed by a lens (not shown) and this condensed light is received by the light receiving portion 32. The light received by the light receiving portion 32 is photoelectrically converted, and the output thereof is input as a sensor signal to a control IC (not shown) formed in an active region. The control IC includes a digital signal processor. The digital signal processor generates still image data or moving image data by processing the sensor signal and outputs it to the substrate (not shown) via the metal wire 37 and the external terminal pin 34. The substrate is connected to a not shown storage device or display device, so that still image data or moving image data is stored in the storage device or displayed on the display device.

In the present embodiment, the camera module 31 includes the semiconductor device 1 in the first embodiment, however, the camera module 31 can include the semiconductor device 21 in the second embodiment instead of the semiconductor device 1 in the first embodiment. Moreover, in the present embodiment, the camera module 31 has a QFP (Quad Flat Package) type package form, however, the camera module 31 can have an LGA (Land Grid Array) or a BGA (Ball Grid Array) type package form.

In the camera module 31 in the present embodiment, the semiconductor device 1 is used, so that the surface (surface formed by the embedded layer 8 and the insulation layer 7 in the fifth process in the first embodiment) of the device layer 33 is formed flat. Therefore, a gap is not generated at the bond interface with the support substrate 10, so that fracture of the multilayer wiring layer 5 in the device layer 33 and distortion of the light receiving portion 32 can be prevented. Thus, it is possible to stably supply the camera module 31 in which the mechanical reliability and the imaging property are improved.

### Fourth Embodiment

FIG. 6 is a schematic diagram illustrating an example of a cross section of a camera module 41 according to the fourth embodiment. The camera module 41 in the present embodiment has a BGA (Ball Grid Array) type package form and includes the semiconductor device 1 in the first embodiment as a main part thereof. In an active region on the surface side of the device layer 33 of the semiconductor device 1, a light receiving portion (for example, CCD imager and CMOS imager) 42 that includes a light receiving element such as a photodiode is provided.

A light-transmissive protective member 43 for protecting the light receiving portion 42 from being damaged or dust is arranged over the device layer 33. The light-transmissive protective member 43 is arranged to cover the surface of the device layer 33. The light-transmissive protective member 43 is adhered to the surface of the device layer 33 via an adhesion layer 44 arranged in the peripheral portion of the surface. A clearance 45 formed based on the thickness of the adhesion layer 44 is present between the light-transmissive protective member 43 and the first surface of the device layer 33. In other words, the light-transmissive protective member 43 is arranged over the light receiving portion 42 provided on the surface of the device layer 33 via the clearance 45.

As the light-transmissive protective member 43, for example, a glass substrate formed of quartz glass, borosilicate glass, or soda-lime glass can be used. For the adhesion layer 44, for example, photosensitive or non-photosensitive epoxy resin, polyimide resin, acrylic resin, or silicon resin can be used. On the light receiving portion 42, typically, a condenser microlens 46 is formed, and the clearance (cavity) 45 is provided between the light-transmissive protective member 43 and the light receiving portion 42 to prevent a light condensing effect of the microlens 46 from being impaired.

On the surface of the light-transmissive protective member 43, an IR (Infrared) (cut) filter 47 that blocks infrared light is formed to cover the light receiving portion 42. Moreover, in a region avoiding the upper portion of the light receiving portion 42, a lens module 50 in which a condenser lens 49 is mounted on a lens holder 48 is attached via an adhesion layer (not shown). In FIG. 6, although only one condenser lens 49 is illustrated, a plurality of the condenser lenses 49 can be formed if needed.

Furthermore, the semiconductor device 1 and the lens module 50 are covered by a shield cap 51 for electric shielding and mechanical reinforcement. The shield cap 51 is, for example, formed of aluminum, a stainless material, or an Fe—Ni alloy (42 alloy or the like). The semiconductor device 1 is mounted on a substrate 52, in which wires (not shown) are formed, via a wiring layer (not shown) that penetrates through the support substrate 10 and external terminals 54 that project from back-side wires 53 and a back-side protective film 55, and is further electrically connected to the wires of the substrate 52.

In such camera module 41, light reached from an imaging object is condensed by the condenser lens 49 and this condensed light is received by the light receiving portion 42. The light received by the light receiving portion 42 is photoelectrically converted, and the output thereof is input as a sensor signal to a control IC (not shown) formed in an active region. The control IC includes a digital signal processor. The digital signal processor generates still image data or moving image data by processing the sensor signal and outputs it to the substrate 52 via the back-side wires 53 and the external terminals 54. The substrate 52 is connected to a not shown storage device or display device, so that still image data or moving image data is stored in the storage device or displayed on the display device.

In the present embodiment, the camera module 41 includes the semiconductor device 1 in the first embodiment, however, the camera module 41 can include the semiconductor device 21 in the second embodiment instead of the semiconductor device 1 in the first embodiment.

In the camera module 41 in the present embodiment, the semiconductor device 1 in the first embodiment is used, so that the surface (surface formed by the embedded layer 8 and the insulation layer 7 in the fifth process in the first embodiment) of the device layer 33 is formed flat. Therefore, a gap is not generated at the bond interface with the support substrate 10, so that fracture of the multilayer wiring layer 5 in the device layer 33 and distortion of the light receiving portion 42 can be prevented. Thus, it is possible to stably supply the camera module 41 in which the mechanical reliability and the imaging property are improved.

### Fifth Embodiment

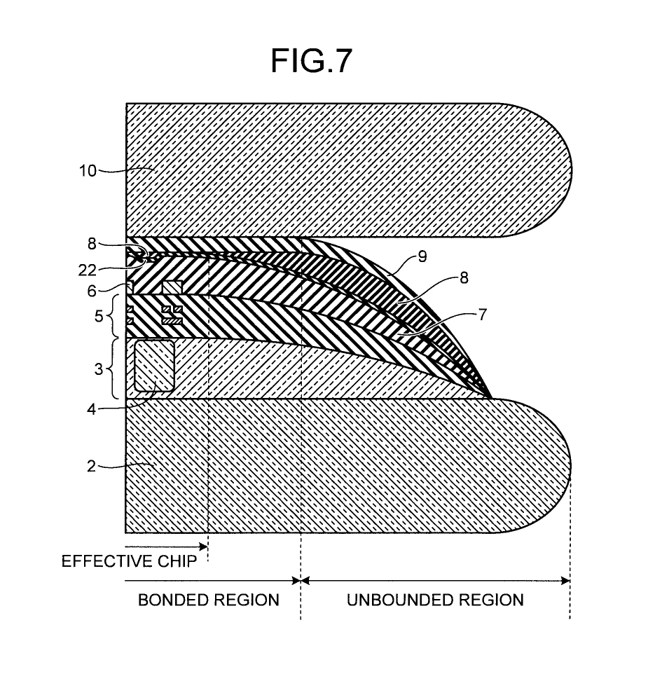

FIG. 7 is a schematic diagram illustrating an example of a cross section of a wafer near the outer periphery thereof according to the fifth embodiment. The wafer in the present embodiment is a wafer in which the semiconductor devices 21 having the same configuration as that in the second embodiment are formed. The semiconductor device 21 having the same configuration as that in the second embodiment is obtained by dicing the wafer in the present embodiment. Components having similar functions to those in the first or second embodiment are denoted by the reference numerals same as those in the first or second embodiment and explanation thereof is omitted. In the following, portions different from the first or second embodiment are explained.

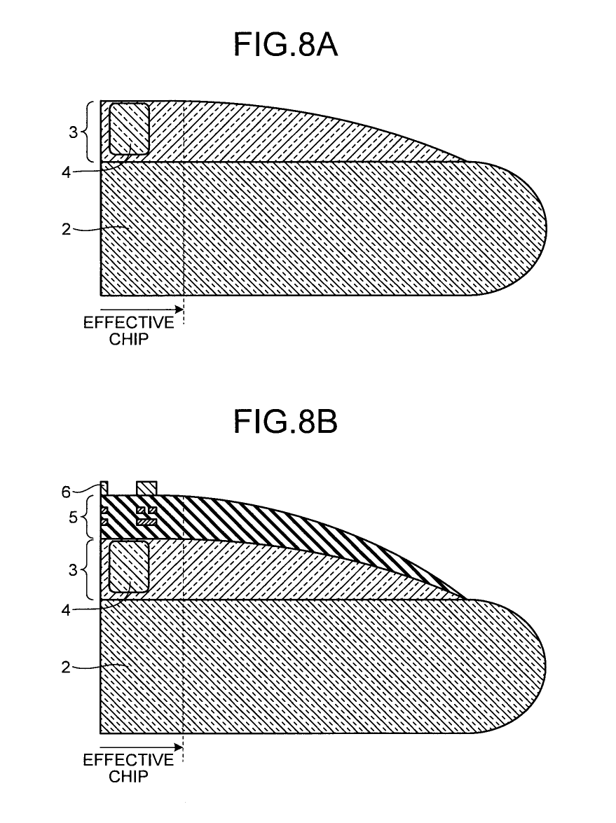

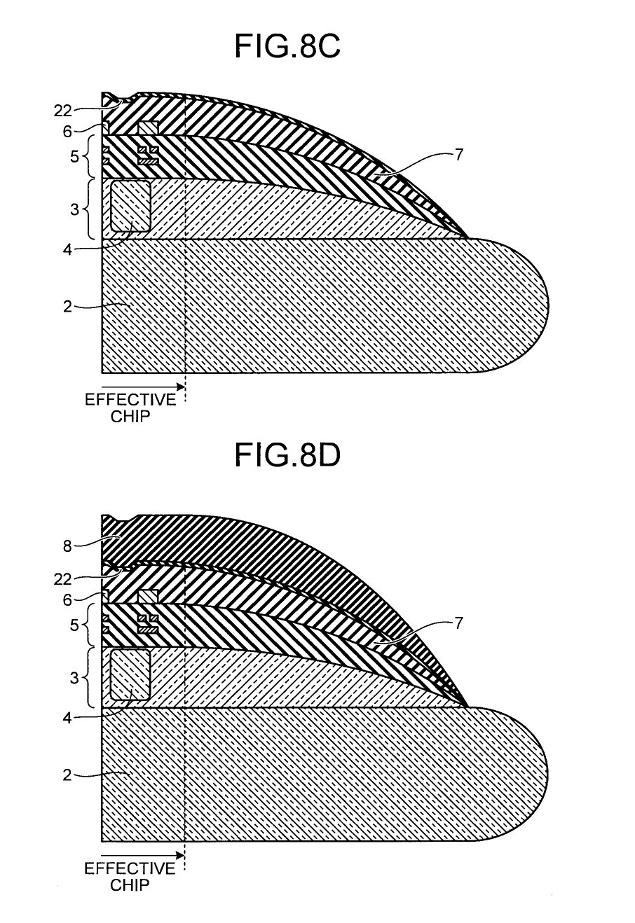

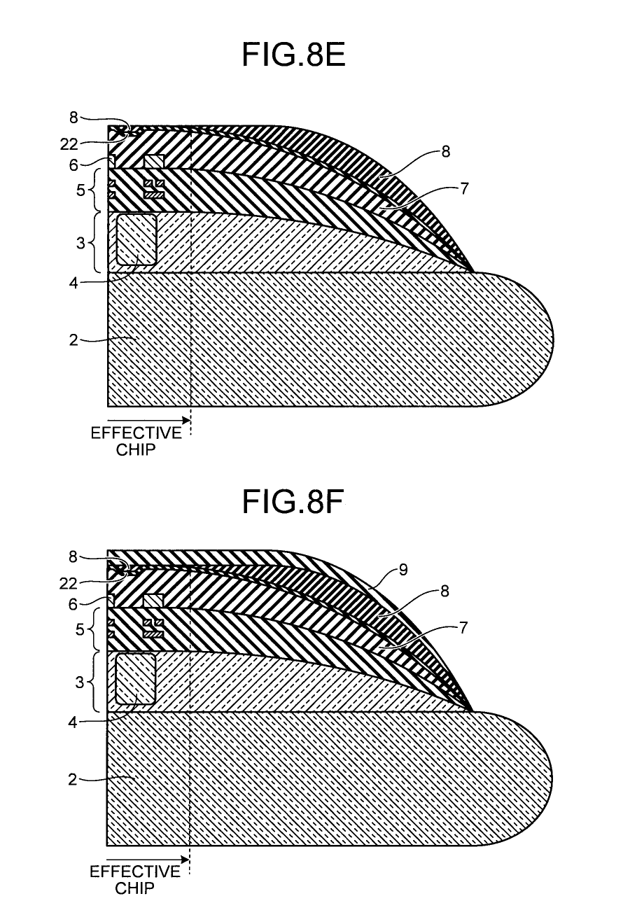

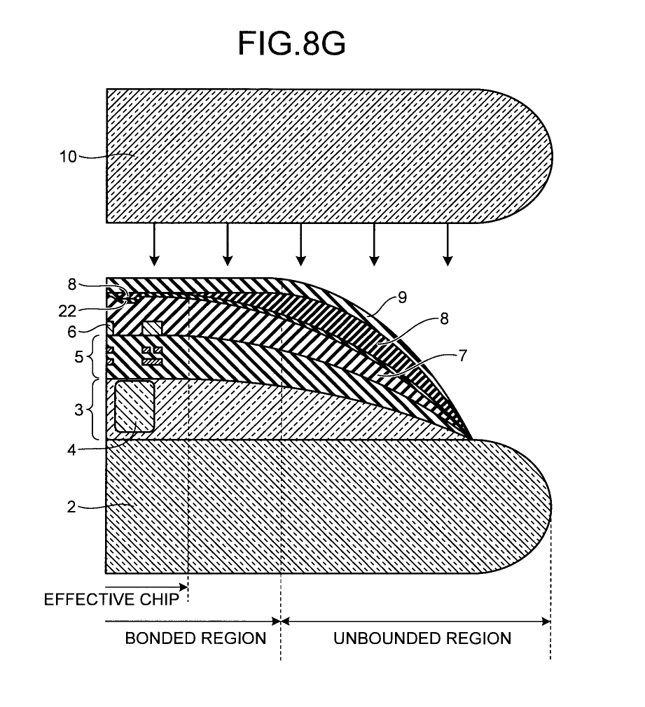

FIG. 8A to FIG. 8G are diagrams illustrating an example of the manufacturing process of the semiconductor device 21 in the present embodiment. FIG. 8A to FIG. 8G illustrate schematic cross sections of the wafer near the outer periphery thereof, in which the semiconductor devices 21 are formed, in respective processes. The parts given the same reference numerals in the drawings indicate the same or corresponding part. In the following, the manufacturing process of the semiconductor device 21 in the present embodiment is explained with reference to FIG. 8A to FIG. 8G.

The first process shown in FIG. 8A and the second process shown in FIG. 8B are similar to the first process and the second process in the second embodiment, respectively. In the first to the second processes, as shown in FIG. 8A to FIG. 8C, near the outer periphery of the wafer, there is a portion (tapered portion) in which each layer becomes thin and the flatness is deteriorated.

After the second process, as the third process as shown in FIG. 8C, first, the stopper layer 22 is formed on the insulation layer 7 in the similar manner to the second embodiment. At this time, the stopper layer 22 is formed up to the outer peripheral end of the wafer to cover the whole insulation layer 7.

Next, in the fourth process, as shown in FIG. 8D, the embedded layer 8 is formed on the stopper layer 22 in the similar manner to the second embodiment. At this time, the embedded layer 8 is formed up to the outer peripheral end of the wafer to cover the stopper layer 22 with sufficient thickness.

In the fifth process shown in FIG. 8E, the embedded layer 8 formed on the stopper layer 22 is thinned by the chemical mechanical polishing from the exposed side that is not in contact with the stopper layer 22. At this time, thinning of the embedded layer 8 is stopped by the stopper layer 22 formed in a flat portion other than the portion near the outer periphery of the wafer, so that the embedded layer 8 remains near the outer periphery of the wafer. Therefore, the flat region can be secured continuously up to the region of part (part of the tapered portion) near the outer periphery of the wafer, enabling to expand the flat region.

Next, in the sixth process shown in FIG. 8F, the bonding layer 9 is formed in the similar manner to the second embodiment. At this time, as explained in the fifth process, because the flat region is expanded by the embedded layer 8, the flat region is expanded also on the surface of the bonding layer 9.

The seventh process shown in FIG. 8G is similar to that in the second embodiment, however, because the flat region on the surface of the bonding layer 9 is expanded, the bonded region when bonding the support substrate 10 thereto is expanded. Thus, stripping of the wafer outer peripheral portion can be reduced.

The eighth process and the ninth process thereafter are similar to the eighth process and the ninth process in the second embodiment and therefore the drawings thereof are omitted.

In this manner, in the present embodiment, the embedded layer 8 is formed up to the outer periphery of the wafer, and the embedded layer 8 near the outer periphery of the wafer is left when the embedded layer 8 is thinned, thereby improving the flatness of the bonded surface. Thus, stripping of the wafer outer peripheral portion can be reduced, enabling to increase the number of effective chips.

What is claimed is:

1. A semiconductor device comprising:
a semiconductor substrate;
an active layer that is formed on one surface of the semiconductor substrate;
a wiring layer that is formed on the active layer and includes a wire to be a convex portion on a surface that is not in contact with the active layer;
a insulation layer that is formed on the wiring layer to have a concave portion;
an embedded layer that is provided on the concave portion of the insulation layer;
a bonding layer that is provided on the insulation layer and the embedded layer; and
a substrate that is bonded to the bonding layer to face the one surface of the semiconductor substrate.

2. The semiconductor device according to claim 1, wherein the concave portion is formed at least in a region other than an upper area of the wiring layer.

3. The semiconductor device according to claim 1, wherein the embedded layer is formed of a metal material.

4. The semiconductor device according to claim 3, wherein the embedded layer is formed of at least any one of a high-resistance metal material and a low-resistance metal material as a single layer or a plurality of layers.

5. The semiconductor device according to claim 1, further comprising a stopper layer between the insulation layer and the embedded layer.

6. The semiconductor device according to claim 5, wherein the concave portion includes a tapered portion in an outer peripheral portion of the substrate.

7. The semiconductor device according to claim 5, wherein
the embedded layer is formed of a material containing a silicon oxide, and
the stopper layer is formed of a silicon nitride.

8. A semiconductor device comprising:
a semiconductor substrate;
a insulation layer that is formed on one surface of the semiconductor substrate to include a concave portion;
an embedded layer that is provided on the concave portion of the insulation layer;
a bonding layer that is provided on the insulation layer and the embedded layer; and
a substrate that is bonded to the bonding layer to face the one surface of the semiconductor substrate.

9. A camera module that includes a semiconductor device having a function as a back-illuminated image sensor, wherein
the semiconductor device includes
a semiconductor substrate,
an active layer that is formed on one surface of the semiconductor substrate to include a light receiving portion,
a wiring layer that is formed on the active layer and includes a wire to be a convex portion on a surface that is not in contact with the active layer,
a insulation layer that is formed on the wiring layer to have a concave portion,
an embedded layer that is provided on the concave portion of the insulation layer,
a bonding layer that is provided on the insulation layer and the embedded layer, and
a support substrate that is bonded to the bonding layer to face the one surface of the semiconductor substrate.

10. The camera module according to claim 9, wherein the concave portion is formed at least in a region other than an upper area of the wiring layer.

11. A method of manufacturing a semiconductor device comprising:
forming an active layer on one surface of a semiconductor substrate;
forming a wiring layer that is formed on the active layer and includes a wire to be a convex portion on a side of a surface that is not in contact with the active layer;
forming a insulation layer on the wiring layer to have a concave portion;
forming an embedded layer on the insulation layer;
removing the embedded layer in a region other than in the concave portion of the insulation layer;
providing a bonding layer on the insulation layer and the embedded layer; and
bonding a substrate to the bonding layer to face the one surface of the semiconductor substrate.

12. The method according to claim 11, wherein the concave portion is formed at least in a region other than an upper portion of the wiring layer.

13. The method according to claim 11, wherein the embedded layer is formed of a metal material.

14. The method according to claim 13, wherein the embedded layer is formed of at least any one of a high-resistance metal material and a low-resistance metal material as a single layer or a plurality of layers.

15. The method according to claim 11, further comprising forming a stopper layer between the insulation layer and the embedded layer.

16. The method according to claim 15, wherein the concave portion includes a tapered portion in an outer peripheral portion of the substrate.

17. The method according to claim 15, wherein
the embedded layer is formed of a material containing a silicon oxide, and
the stopper layer is formed of a silicon nitride.

18. The method according to claim 10, wherein the removing the embedded layer is performed by a chemical mechanical polishing.
